(19) United States
(12) Patent Application Publication
(10) Pub. No.: US 2006/0273340 A1
(43) Pub. Date: Dec. 7, 2006

(54) LED package and method using the same

(76) Inventor: Daming LV, Xili Town (CN)

Correspondence Address: KNOBBE MARTENS OLSON & BEAR LLP, 2040 MAIN STREET, FOURTEENTH FLOOR, IRVINE, CA, 92614, US

(21) Appl. No.: 11/231,645

(22) Filed: Sep. 21, 2005

(30) Foreign Application Priority Data
Jun. 7, 2005 (CN) 200510021051.3

(51) Int. Cl. H01L 29/24

(52) U.S. Cl. 257/100

(57) ABSTRACT

An LED package including an LED chip (LA, A, B), a sealed transparent envelope (D) containing the LED chip inside, transparent liquid (E) filled in the envelope, electrodes (C) is disclosed. The LED chip comprises a plurality of conductive nodes. The transparent liquid is provided with a high resistance, the resistance of the liquid being higher than on-state resistance of the LED chip. The electrodes are respectively connected with the conductive nodes. The electrodes are extended out from the sealed envelope to be electrically connected with an exterior circuit. A method forming an LED package comprises steps: providing an LED chip, encapsulating the LED chip with a transparent encapsulating envelope; transparent liquid provided with high resistance accommodated in the envelope.

### BACKGROUND OF THE INVENTION

1. Field of the Invention

The present invention relates generally to a light emitting diode (LED) packaging and method of manufacturing and using the same.

2. Description of the Related Art

In 1879, Thomas Edison invented the electric bulb. From then on, artificial light source is regarded as a commodity. From the earliest carbon filament electric bulbs with only eight-hour life to modern forms of tungsten filament bulbs, fluorescent lamps, sodium lamps, mercury lamps and the like, artificial light sources vary greatly in design. Long life-span, high quantity of light, and low power consumption are concerns for research and design.

LEDs are semiconductors and transform electrical energy to visible light at electric fields different from fluorescent lamps or bulbs. LEDs have a long life amounting to millions of hours, high quantity of light, no radiation, and low power consumption. Spectrum of an LED is distributed in the visible region. Luminescent ratio can reach eighty percent or ninety percent, and the quantity of light is high without radiation. An LED is a luminescent source without environmental pollution.

Since the first commercial germanium LED, manufacture of LEDs has been well developed. Concerning the research and development of LEDs, two issues are raised.

One issue is LED power supply circuit design. It is important to provide stable and pure current, so as to prolong LEDs' life. Many rectifier elements are provided, such as resistances, transformers, selenium rectifiers, and complicated switching powers, such that a designer can choose a suitable element to complete an LED power supply circuit. Chinese Patent Application Nos. 200410040265.0 and No. 200420061456.0 disclose large scale luminescent appliance solutions.

Another issue is LED performance improvement. The research and development of LEDs focuses on two aspects. The first aspect is the LED material used in manufacturing. Up to now, every significant improvement of LED is rooted in appliance and innovation of new materials. The early red LED made of Germanium and GaAsP can provide a luminous flux of 0.1 Lumen per Watt. After this, luminous flux of a GaAsP LED with nitrogen mixing craft reaches 1 Lumen per Watt, and the GaAsP LED can glow with red, orange, and yellow light. In 1971, a green bare LED made of GaP with the same luminous flux was developed. An AlGaAs LED was developed in early 1980's and it can provide a luminous flux of 10 Lumens per Watt. Now, an LED can provide a luminous flux of 100 Lumens per Watt.

The second aspect is LED package. LED package design is developed around and varies from an early package design with two pins, such as cylindrical type, conical type, and strawhat type, to package with high power PLCC species, such as piranha species, and so on. In research and design of high power LEDs, packaging is becoming more critical because of its influence on LED luminescent performance. LED chips encapsulated in different packaging means can provide different results with regard to luminescent performance. A goal of LED research and design is to provide luminescent ability of each LED in a maximum range and, at the same time, settle thermoconductivity and thermodiffusion issues.

In a conventional LED package, a solid package with a support bracket is provided. It comprises a substrate pad, a semiconductor chip interconnected with a plurality of pins and a hull associated with the current state of the art. With high power consumption and high thermal diffusion, a plurality of accessories is combined with the LED package, for example, a thermal absorber lying under the substrate receiving the semiconductor chip, a plurality of thermal fins extending from the inner pins of the package. The bracket should be rigid and tough enough to function as a support for the package, thermal absorbing and diffusion, and conducting electricity. The critical performance requirements of the bracket result in difficulties in manufacturing and high cost of LEDs, thus restricting development in LED industry.

In a conventional LED package, self-thermolysis is a considering factor for reaching a predetermined thermal coefficient. Improved thermal coefficient is affected by modifying some configuration of LED within the narrow mounting space above the bracket. In a typical LED package with an advanced bracket, structure, the whole package configuration provides for LED chips that have a thermal requirement within 300 mW and the luminescent flux below 40 Lumens per Watt. However, with high power LED requirement, and outdoor or indoor requirements of large scale or concentrated or high intensity illuminations, the traditional LED package and thermal means cannot fulfill the requirement and should be improved.

### SUMMARY OF THE INVENTION

In light of the foregoing, there is a need to improve the packaging design of an LED. There is a need to provide a new and improved method of fabricating LED arrays and packaging that can support higher power consumption chips and more thermal efficient than prior methods, and which is easily adaptable to high production levels.

An embodiment provides an LED package, comprising:

an LED chip, the LED chip comprising a luminescent transistor and a plurality of conductive nodes;

a sealed transparent or partly transparent envelope, containing the LED chip inside; and

transparent liquid accommodated in the envelope, the liquid provided with high resistance, the resistance of the liquid being much higher than on-state resistance of the LED chip; and

a plurality of electrodes, each electrode connected with one of the conductive nodes, the electrodes joining the conductive nodes extended out from the sealed envelope to be electrically connected with an exterior circuit.

### BRIEF DESCRIPTION OF THE DRAWINGS

FIG. 1 shows a schematic view of an LED chip in LED package in accordance with a preferred embodiment, comprising six single chips in series and parallel connection.

FIG. 2 shows a schematic view of the LED package of a preferred embodiment, with a preferred straight structure of the LED chip, comprising the LED chip in series and parallel connection and an encapsulating envelope receiving the LED chip.

FIG. 3 shows a schematic view of the LED package in accordance with a preferred embodiment, showing an alternative U-shaped structure of the LED chip.

FIG. 4 shows section views of the LED package of a preferred embodiment; FIG. 4a shows an axial symmetry package with exterior fluorescent layer thereof; FIG. 4b shows an axial symmetry package with interior fluorescent layer thereof; FIG. 4c shows an axial symmetry package with sandwiched fluorescent layer thereof.

FIG. 5 shows a section view of the LED package of a preferred embodiment, showing an axial symmetry package with interior reflector.

FIG. 6 shows a schematic view of illuminating area the LED package of a preferred embodiment, presenting the elliptic transparent encapsulating envelope.

### DETAILED DESCRIPTION OF THE PREFERRED EMBODIMENT

A preferred embodiment provides an LED package and method using the same for better thermal conditions and high luminescent efficiency. The preferred embodiments mitigate and/or obviate disadvantages of a conventional LED package.

In a preferred embodiment, an LED package comprises an LED chip, a sealed transparent envelope containing the LED chip inside, a transparent liquid filled inside the envelope, and electrodes. The LED chip comprises luminescent transistors and conductive nodes, and each of conductive nodes is connected with one of electrodes.

The LED chip can have various embodiments. In one embodiment, the LED chip is a straight linear type, and electrodes are respectively extended out from two endpoints of the sealed transparent envelope. In another embodiment, the LED chip is U shape, and electrodes are simultaneously extended out from the sealed transparent envelope by the same side.

The transparent envelope of the package can have different figurations, such as sphere type, elliptic type, and cylindrical type. The transparent liquid is provided with high resistance. Preferably, the resistance of the liquid is higher than on-state resistance of the LED chip so as to avoid interferences between the liquid and the LED chip.

The electrodes are extended out from the sealed envelope to be electrically connected with an exterior circuit. In a preferred embodiment, a fluorescent layer is combined with the envelope, covering the exterior surface of the envelope, or sticking to the interior surface of the envelope, or material of the transparent envelope is compounded with fluorescent dosage, or the fluorescent layer is sandwiched in the envelope of the package. In other embodiments, a reflector layer is provided. The reflector sticks to the envelope under the surface interiorly or over the surface exteriorly thereof, or is sandwiched in the envelope, with different angles or directions according to light intensity.

A method forming an LED package of the preferred embodiments comprises the following steps: providing an LED chip; encapsulating the LED chip with a transparent encapsulating envelope; providing a transparent liquid with high resistance in the envelope. The LED chip comprises two conductive nodes or more; each of the conductive nodes is connected with an electrode. The electrodes joining the conductive nodes are extended out from the envelope. Preferably, resistance of the liquid is much higher than on-state resistance of the LED chip.

Referring to FIG. 1, the preferred embodiment relates to a packaging design for LED. The LED package in accordance with the preferred embodiment comprises an LED chip, transparent encapsulating envelope encasing the LED chip, electrodes connecting the chip with exterior power supply, and encapsulating liquid. Conductive nodes of the chip respectively join one of the electrodes. The transparent encapsulating envelope encapsulates the chip and is filled with the liquid. The electrodes penetrate through the encapsulating envelope, and form an electric connection between the inner LED chip and an outer system circuit.

Preferably, the liquid inside the encapsulating envelope can be transparent and can have resistance much higher than the on-state resistance of the LED chip so that current runs through the working LED chip.

Comparing a traditional LED package with the liquid package of the present embodiment, the traditional package utilizes thermal absorbing accessories or self-thermolysis. The LED package of the present embodiment has additional thermal approaches. One is thermal convection of the sealed liquid; the other is the increase of thermal region. When the LED chip is immersed in the liquid inside the encapsulating envelope, there is no need of a support base, and light that used to be sheltered by support base scatters and less heat is transferred from light. The entire LED package of the present embodiment presents a sphere illumining area, so the luminescent ratio is improved.

Referring to FIG. 1, the LED chip of the preferred embodiment can be in traditional configurations, comprising a single chip or a chipset. A plurality of wafers, abbreviation L, having the same or different color, combined in series connection or parallel connection are shown in FIG. 1. The LED chip of combined wafers L, named LA, is adapted for alternating current. The LED chip LA comprises two groups of wafers L. Each group comprises three wafers L, with the series being connected with one another. The two group wafers are in parallel connection in accordance with reversal conductive theory. Electrodes are respectively indicated as “+” or “−” at two endpoints of each wafer L. CN represents conductive node of the whole chip LA. BS represents basic underlay materials.

According to the manufacturing technique of LEDs, the luminescent transistor is formed from the basic underlay BS. A luminescent transistor of the present embodiment can be conventional with regard to photic property and low light attenuation. With regard to LED manufacture technique, no extra attention need be provided to the basic underlay BS. In a preferred embodiment, the luminescent transistor can be independently packaged. The package comprising the liquid and the method using the same can be applied to obtain improved performance of an LED compared to prior art LEDs.

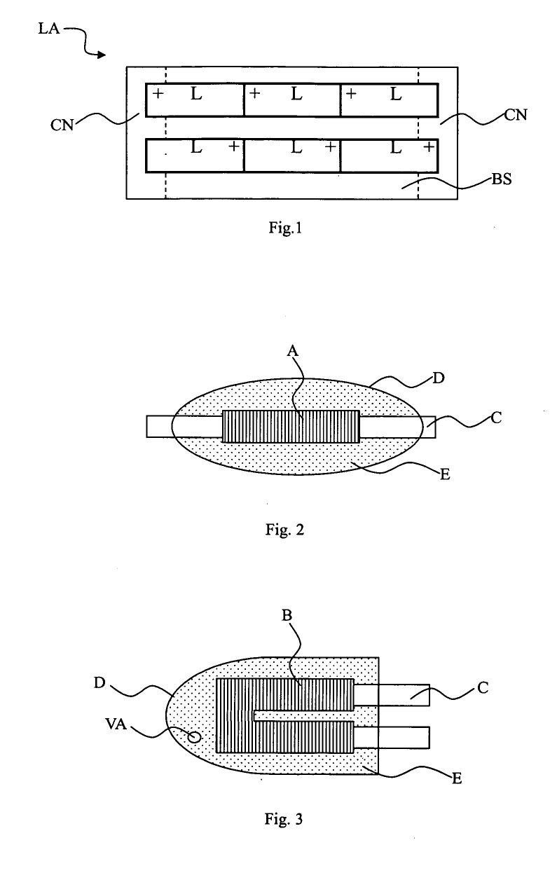

Referring to FIG. 2 and FIG. 3, LED chip LA can have a regular shape or different figurations. In certain situations, a figuration change of LED chip can improve its properties, especially in high power consumption chips. FIG. 2 shows a straight type LED chip A. Two electrodes respectively stick out of an encapsulating envelope D from individual endpoints thereof. The straight type LED chip can be adapted for a regular lamp pipe or an end to end situation. FIG. 3 shows a U shape LED chip B. Two electrodes simultaneously extend out of the encapsulating envelope D at the same endpoint thereof. The U shape LED chip can be adapted for a plug and play appliance.

Based on simplified configurations and space layout of the present embodiment, the electrodes extending from the conductive nodes of the LED chip can be a flat leaf, so as to broaden contacting surface between the liquid inside the encapsulating envelope and the electrode, thereby improving thermal and electric conductance property. The flat and leaf like electrode can be made of economic materials with good electric and thermal conductance property, such as, but not limited to copper and aluminum.

Encapsulated liquid is a feature of the present embodiment. Preferably, the encapsulated liquid is transparent and has hydrodynamic property to form thermal hydro convection. Preferably, the encapsulating liquid has a stable chemical property and resistance higher than the on-state resistance of the LED chip. With these properties, there are an avoidance of interferences upon transistors, reliability of the LED chip, and a longer life of the LED chip.

High purity water is a qualified and economic choice for the encapsulated liquid. Whether encapsulating liquid alters light wavelength coming from luminescent transistors is not a concern of the present embodiment and can be explored through a research setting.

Referring to FIG. 2, the liquid E is filled inside the elliptic encapsulating envelope D, with a standard package method known in the art. A vacuum portion or bubbles can remain in the envelope D. Referring to FIG. 3, liquid E and vacuum bubbles VA are provided in the encapsulating envelope D. With this embodiment, the LED can be used under certain circumstances, for example, achieving phantasmagoric light appearance. It should be noted that the number of bubbles can affect thermal diffusion.

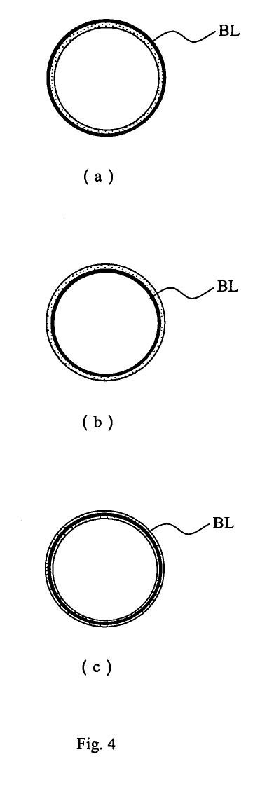

The encapsulating envelope D can be variable in appearance. Preferably, the encapsulating envelope D is transparent. For better performance, materials of low light attenuation should be used. For instance, a fluorescent layer can be used in some manner—such as covering the exterior surface of the encapsulating envelope, coating under the surface of encapsulating envelope, or the envelope D comprises fluorescent dosage, or a fluorescent layer is sandwiched in the envelope D—to change the light wavelength of LED. An LED incorporating different fluorescent materials can result in different luminescent results. Also, FIG. 4a to FIG. 4c show different combinations of the fluorescent layer with the encapsulating envelope, covering the exterior surface of the envelope, or sticking to the inner surface of the envelope, or sandwiched inside the encapsulating envelope. The black loop shown in FIG. 4a, FIG. 4b, and FIG. 4c, abbreviation BL, represents the fluorescent layer. Dotted loop indicates the encapsulating envelope.

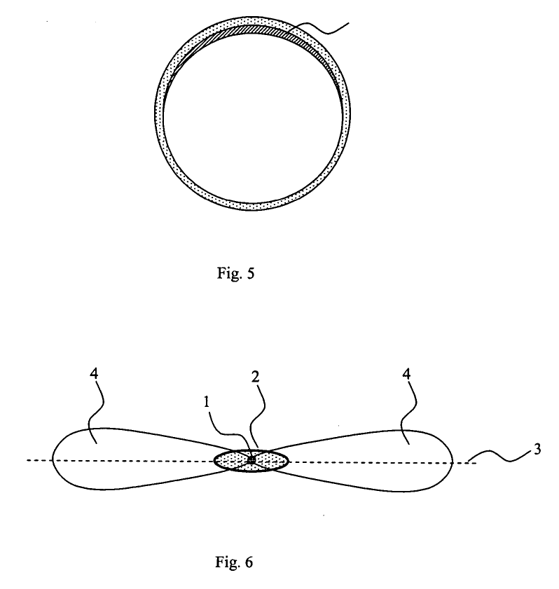

Referring to FIG. 5, an LED incorporating different reflectors can have different results. A reflector can be placed inside or outside of the envelope, or be sandwiched in the envelope, with different angles or directions according to light intensity, so as to shelter a portion thereof and to achieve goals of predetermined illumination or control of luminescent area. FIG. 5 illustrates a relationship between the reflector and the encapsulating envelope. The portion with slant lines indicates the reflector, abbreviated RE. The dotted loop represents the encapsulating envelope.

Referring to FIG. 6, different figurations can result in different luminescent outputs. For example, a sphere transparent envelope package can imitate traditional sphere lamp illumination. A cylindrical transparent envelope can imitate a linear lamp, such as a fluorescent lamp. An elliptic transparent encapsulating envelope can imitate an indicator lamp. Referring to FIG. 6, a transparent elliptic encapsulating envelope package 2 is shown. In a preferred embodiment, the rays generated form transistors in LED chip 1 can gather in area 4 along long axis 3 of the elliptic encapsulating envelope 2. This kind of LED package described above can be utilized as a pilot lamp in navigations.

According to the fore mentioned detail description, implementation and appliance of the LED package and method using the same can bring about an LED industry revolution and push brand new developments in LED research.

While the present invention has been illustrated by the description of preferred embodiments thereof, and while the preferred embodiments have been described in considerable detail, it is not intended to restrict or in any way limit the scope of the appended claims to such detail. Additional advantages and modifications within the spirit and scope of the present invention will readily appear to those skilled in the art. Therefore, the present invention is not limited to the specific details and illustrative examples shown and described.

What is claimed is:

1. An LED package, comprising:
an LED chip, the LED chip comprising a luminescent transistor and a plurality of conductive nodes;
a sealed transparent or partly transparent envelope, containing the LED chip inside; and
transparent liquid accommodated in the envelope, the liquid provided with high resistance, the resistance of the liquid being much higher than on-state resistance of the LED chip; and
a plurality of electrodes, each electrode connected with one of the conductive nodes, the electrodes joining the conductive nodes extended out from the sealed envelope to be electrically connected with an exterior circuit.

2. The LED package according to claim 1, wherein the LED chip is a straight linear type, and electrodes are respectively extended out from two endpoints of the sealed transparent envelope.

3. The LED package according to claim 1, wherein the LED chip is U shape, and electrodes are simultaneously extended out from the sealed transparent envelope by the same side.

4. The LED package according to claim 1, wherein a fluorescent layer is combined to the sealed transparent envelope, covering the exterior surface of the envelope, or sticking to the interior surface of the envelope, or material of the transparent envelope is compounded with fluorescent dosage, or the fluorescent layer is sandwiched in the envelope of the package.

5. The LED package according to claim 1, wherein a reflector layer sticks to the envelope under the surface interiorly or over the surface exteriorly thereof, or is sandwiched in the envelope, with different angles or directions according to light intensity.

6. The LED package according to claim 1, wherein the transparent liquid fills the envelope.

7. The LED package according to claim 1, wherein the sealed envelope is transparent.

8. The LED package according to claim 7, wherein the sealed transparent envelope of the package is sphere type, elliptic type, or cylindrical type.

9. A method of forming an LED package comprising:
providing an LED chip, the LED chip comprising a plurality of conductive nodes, each conductive node connected with an electrode;
encapsulating the LED chip with a transparent or partly transparent encapsulating envelope;
providing a transparent liquid with high resistance in the envelope, wherein the resistance of the liquid is higher than on-state resistance of the LED chip; and
joining the electrodes with the conductive nodes extended out from the encapsulating envelope.
